(19) United States
(12) Patent Application Publication
(10) Pub. No.: US 2024/0071899 A1
(43) Pub. Date: Feb. 29, 2024

(54) SEMICONDUCTOR PACKAGE AND MANUFACTURING METHOD THEREOF

(71) Applicant: Samsung Electronics Co., Ltd., Suwon-si (KR)

(72) Inventors: Gyuho KANG, Suwon-si (KR); Hyungjun PARK, Suwon-si (KR); Seonghoon BAE, Suwon-si (KR); Sanghyuck OH, Suwon-si (KR); Kwangok JEONG, Suwon-si (KR); Juil CHOI, Suwon-si (KR)

(73) Assignee: Samsung Electronics Co., Ltd., Suwon-si (KR)

(21) Appl. No.: 18/450,836

(22) Filed: Aug. 16, 2023

(30) Foreign Application Priority Data
Aug. 29, 2022 (KR) 10-2022-0108728

(51) Int. Cl. H01L 23/498; H01L 21/48; H01L 23/538; H01L 25/10

(52) U.S. Cl. CPC H01L 23/49866; H01L 21/4857; H01L 23/49822; H01L 23/5383; H01L 25/105; H01L 24/16

(57) ABSTRACT

Provided is a semiconductor package. The semiconductor package including a redistribution structure including a plurality of redistribution conductive patterns, a plurality of conductive vias connected to at least one of the plurality of redistribution conductive patterns, a plurality of lower pads connected to the plurality of conductive vias, and a plurality of redistribution insulation layers and the plurality of redistribution conductive patterns alternating each other, a semiconductor chip arranged on the redistribution structure, and an external connection terminal attached to the plurality of lower surface pads of the redistribution structure, wherein each of the plurality of redistribution conductive patterns includes a metal layer including copper and a skin layer arranged on an upper surface of the metal layer and including copper and nickel, may be provided.

### CROSS-REFERENCE TO RELATED APPLICATION

This application is based on and claims priority under 35 U.S.C. § 119 to Korean Patent Application No. 10-2022-0108728, filed on Aug. 29, 2022, in the Korean Intellectual Property Office, the disclosure of which is incorporated by reference herein in its entirety.

### BACKGROUND

The inventive concepts relate to semiconductor packages and/or manufacturing methods thereof, and more particularly, to fan-out semiconductor packages and/or manufacturing methods thereof.

With the rapid development of the electronics industry and the demands of users, electronic devices are becoming smaller and lighter. Accordingly, semiconductor devices, which are core components of electronic devices, are required to be highly integrated. In addition, as mobile products develop, miniaturization and multi-functionalization are also required.

### SUMMARY

The inventive concepts provide a semiconductor package having improved reliability of a redistribution structure.

The inventive concepts provide a method of manufacturing a semiconductor package capable of simplifying a process of forming a redistribution structure.

According to an aspect of the inventive concepts, there is provided a semiconductor package including a redistribution structure including a plurality of redistribution conductive patterns, a plurality of conductive vias connected to at least one of the plurality of redistribution conductive patterns, a plurality of lower pads connected to one of the plurality of conductive vias, and a plurality of redistribution insulation layers and the plurality of redistribution conductive patterns alternating with each other, a semiconductor chip on the redistribution structure, and an external connection terminal attached to the plurality of lower surface pads of the redistribution structure, wherein each of the plurality of redistribution conductive patterns includes a metal layer including copper, and a skin layer on an upper surface of the metal layer and including copper and nickel.

According to another aspect of the inventive concepts, there is provided a semiconductor package including a first redistribution structure including a plurality of first redistribution conductive patterns, a plurality of first conductive vias connected to at least one of the plurality of first redistribution conductive patterns, a plurality of lower pads connected to the plurality of first conductive vias, and a plurality of first redistribution insulation layers and the plurality of first redistribution conductive patterns alternating with each other, a semiconductor chip on the first redistribution structure, a connection structure on the first redistribution structure and spaced apart from the semiconductor chip in a horizontal direction, and a second redistribution structure on the connection structure and including a plurality of second redistribution conductive patterns, a plurality of second conductive vias connected to at least one of the plurality of second redistribution conductive patterns, and a plurality of second redistribution insulation layers and the plurality of second redistribution conductive patterns alternating with each other, wherein at least one of the plurality of first redistribution conductive patterns and the plurality of second redistribution conductive patterns includes a metal layer including copper, and a skin layer on an upper surface of the metal layer and including copper and nickel.

According to another aspect of the inventive concepts, there is provided a semiconductor package including a first redistribution structure, a semiconductor chip on the first redistribution structure, a connection structure on the first redistribution structure and spaced apart from the semiconductor chip in a horizontal direction, a second redistribution structure on the connection structure and being at a higher vertical level than the semiconductor chip, and an external connection terminal on a bottom surface of the first redistribution structure, wherein the first redistribution structure includes a first conductive pattern, a first insulation layer covering the first conductive pattern and including a first via hole exposing a portion of an upper surface of the first conductive pattern, a conductive via in the first via hole and on the portion of the upper surface of the first conductive pattern, a second conductive pattern on the first insulation layer and integrally connected to the conductive via, and a second insulation layer covering the second conductive pattern, and wherein each of the first conductive pattern and the second conductive pattern includes a metal layer including copper, and a skin layer on an upper surface of the metal layer and including Cu₁₋ₓNiₓ (x is 0.2 to 0.8).

According to another aspect of the inventive concepts, a method of manufacturing a semiconductor package may include forming a first insulation layer having a first via hole on a support carrier, forming a metal layer including copper to fill the first via hole on the first insulation layer, forming a finishing layer including nickel on the metal layer, wherein the finishing layer has a thickness of 150 to 300 angstroms, applying a second insulation layer covering the metal layer and the finishing layer on the first insulation layer, and curing the second insulation layer at a temperature of 200° C. to 300° C., wherein, in the curing step, a skin layer including copper and nickel is formed from at least a portion of the finishing layer.

According to another aspect of the inventive concepts, a method of manufacturing a semiconductor package may include forming a first insulation layer having a first via hole on a support carrier, forming a metal layer including copper to fill the first via hole on the first insulation layer, forming a finishing layer including nickel on the metal layer, and forming a second insulation layer covering the metal layer and the finishing layer on the first insulation layer, wherein, in the forming of the second insulation layer, copper atoms included in the metal layer are diffused into the finishing layer so that the finishing layer is converted into a skin layer, and the skin layer includes Cu₁₋ₓNiₓ (x is 0.2 to 0.8).

### BRIEF DESCRIPTION OF THE DRAWINGS

Some example embodiments of the inventive concepts will be more clearly understood from the following detailed description taken in conjunction with the accompanying drawings in which:

FIG. 1 is a cross-sectional view illustrating a semiconductor package according to an example embodiment;

FIG. 2 is an enlarged view of a portion CX1 of FIG. 1;

FIG. 3 is an enlarged view of a portion CX2 of FIG. 1;

FIGS. 4 and 5 are enlarged views of a portion CX3 of FIG. 2;

FIG. 6 is a cross-sectional view illustrating a semiconductor package according to an example embodiment;

FIG. 7 is an enlarged view of a portion CX1 of FIG. 6;

FIG. 8 is a cross-sectional view illustrating a semiconductor package according to an example embodiment;

FIG. 9 is a cross-sectional view illustrating a semiconductor package according to an example embodiment;

FIG. 10 is a cross-sectional view illustrating a semiconductor package according to an example embodiment;

FIG. 11 is a cross-sectional view illustrating a semiconductor package according to an example embodiment;

FIG. 12 is an enlarged view of a portion CX4 of FIG. 11;

FIG. 13 is a cross-sectional view illustrating a semiconductor package according to an example embodiment; and

FIGS. 14 to 21 are cross-sectional views illustrating a method of manufacturing a semiconductor package, according to an example embodiment.

### DETAILED DESCRIPTION

Hereinafter, some example embodiments of the inventive concepts will be described in detail with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of” (as well as “any one of”), when preceding a list of elements, modify the entire list of elements and do not modify the individual elements of the list. Thus, for example, both “at least one of A, B, or C” and “at least one of A, B, and C” mean either A, B, C or any combination thereof.

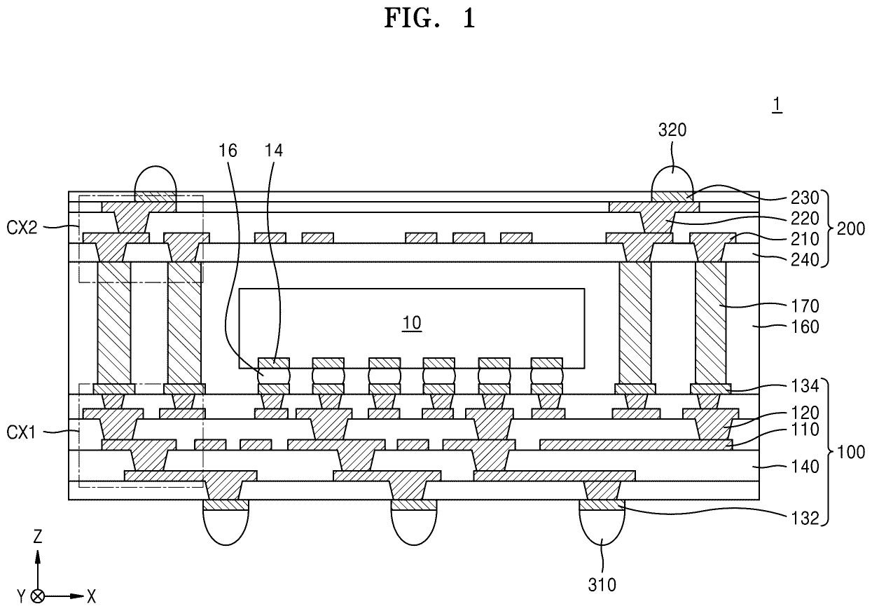

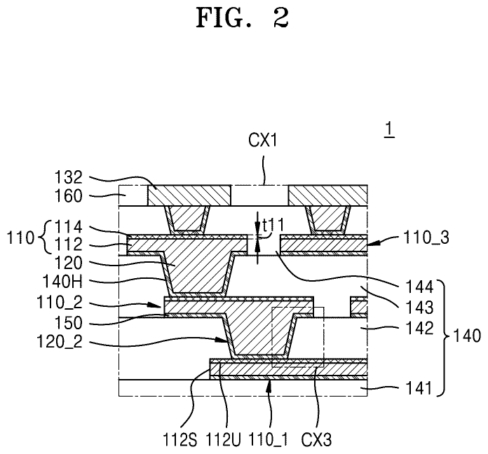

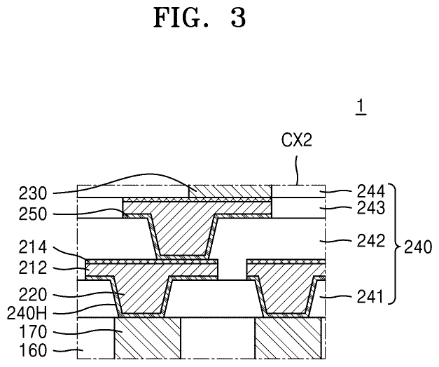

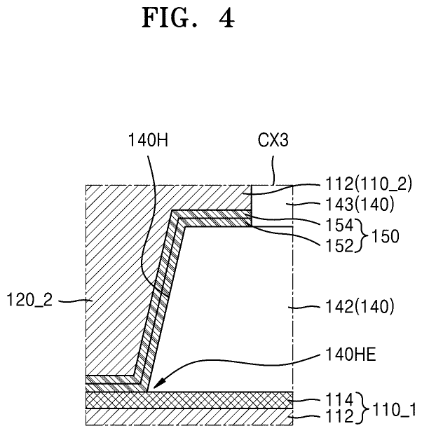

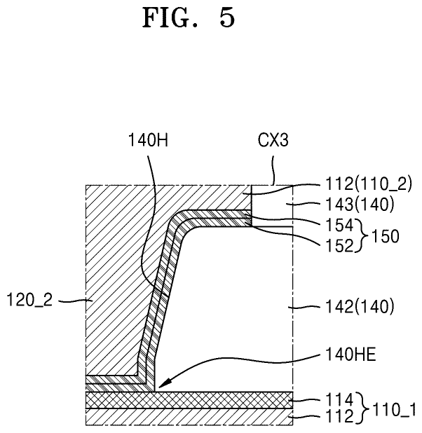

FIG. 1 is a cross-sectional view illustrating a semiconductor package 1 according to an example embodiment. FIG. 2 is an enlarged view of a portion CX1 of FIG. 1. FIG. 3 is an enlarged view of a portion CX2 of FIG. 1. FIGS. 4 and 5 are enlarged views of a portion CX3 of FIG. 2.

Referring to FIGS. 1 to 5, the semiconductor package 1 may include a semiconductor chip 10, a first redistribution structure 100, an expansion layer 160, a connection structure 170, a second redistribution structure 200, and a plurality of external connection terminals 310.

The semiconductor chip 10 may be mounted on the first redistribution structure 100, and the expansion layer 160 may surround the semiconductor chip 10 on the first redistribution structure 100. The connection structure 170 may be arranged through the expansion layer 160 on the upper surface of the first redistribution structure 100, and the second redistribution structure 200 may be arranged on the semiconductor chip 10, the expansion layer 160, and the connection structure 170.

The semiconductor chip 10 may be arranged on the first redistribution structure 100. For example, the semiconductor chip 10 may be mounted on the first redistribution structure 100 in a flip chip manner. The semiconductor chip 10 may be a memory chip or a logic chip. The memory chip may be, for example, a volatile memory chip such as DRAM or SRAM, or may be a nonvolatile memory chip such as phase-change random access memory (PRAM), magnetoresistive random access memory (MRAM), ferroelectric random access memory (FeRAM), or resistive random access memory (RRAM). In addition, the logic chip may be, for example, a microprocessor, an analog device, or a digital signal processor.

The semiconductor chip 10 may include, for example, silicon (Si). In some example embodiments, the semiconductor chip 10 may include semiconductor elements such as germanium (Ge), or compound semiconductors such as silicon carbide (SiC), gallium arsenide (GaAs), indium arsenide (InAs), and indium phosphide (InP). The semiconductor chip 10 may have an active surface and an inactive surface opposite to the active surface. The active surface of the semiconductor chip 10 may face the first redistribution structure 100. Semiconductor devices including various types of multiple individual devices may be formed on the active surface of the semiconductor chip 10. For example, the multiple individual devices may include various microelectronic devices, such as complementary metal-oxide semiconductor (CMOS) transistors, metal-oxide-semiconductor transistors (MOSFETs), system large-scale integration (LSI), image sensors such as CMOS imaging sensors (CIS), micro-electromechanical system (MEMS), active devices, passive devices, and others.

In an example embodiment, the semiconductor package 1 is a semiconductor package having a fan-out structure, and the footprint of the semiconductor chip 10 may be smaller than the footprint of the first redistribution structure 100. That is, at least one of a plurality of external connection terminals 310 may be arranged at a position spaced apart outward from the side surface of the semiconductor chip 10.

The semiconductor package 1 may include a plurality of semiconductor chips. For example, the semiconductor package 1 may include two or more semiconductor chips. The plurality of semiconductor chips may be homogeneous semiconductor chips or heterogeneous semiconductor chips. The semiconductor package 1 may be a system in package (SIP) in which heterogeneous semiconductor chips are electrically connected to each other and operate as one system.

The first redistribution structure 100 may include a plurality of first redistribution conductive patterns 110, a plurality of first conductive vias 120, a plurality of bottom pads 132, a plurality of first top pads 134, and a plurality of first redistribution insulation layers 140. The plurality of first conductive vias 120 may be connected to the plurality of first redistribution conductive patterns 110, and the plurality of bottom pads 132 may be connected to the lowermost first conductive vias 120. A plurality of first redistribution insulation layers 140 may cover the plurality of first redistribution conductive patterns 110, the plurality of first conductive vias 120, and the plurality of bottom pads 132.

As shown in FIG. 2, the plurality of first redistribution insulation layers 140 may have a structure in which four insulation layers are stacked. For example, the plurality of first redistribution insulation layers 140 may include a first insulation layer 141, a second insulation layer 142, a third insulation layer 143, and a fourth insulation layer 144 and the first to fourth insulation layers 141, 142, 143, and 144 may be stacked vertically and may cover the plurality of first redistribution conductive patterns 110 arranged between the first to fourth insulation layers 141, 142, 143, and 144. However, the number of stacked layers of the plurality of first redistribution insulation layers 140 is not limited to four illustrated in FIG. 2, and three or less or five or more insulation layers may be stacked. In some example embodiments, the plurality of first redistribution insulation layers 140 may include a photosensitive insulation material such as a photo-imageable dielectric (PID) material.

As illustrated in FIG. 2, the plurality of first redistribution conductive patterns 110 may include a metal layer 112 and a skin layer 114 arranged on an upper surface 112U of the metal layer 112. Here, the upper surface 112U of the metal layer 112 may refer to a surface placed at a higher vertical level, for example, a surface placed closer to the semiconductor chip 10, among two opposite surfaces of the metal layer 112 that extend horizontally and face each other, in each of the plurality of first redistribution conductive patterns 110. The skin layer 114 covers the entire upper surface 112U of the metal layer 112, and accordingly, the upper surface 112U of the metal layer 112 may not directly contact the plurality of first redistribution insulation layers 140. The skin layer 114 may not be arranged on a sidewall 112S of the metal layer 112, and the sidewall 112S of the metal layer 112 may be covered by the plurality of first redistribution insulation layers 140.

In some example embodiments, the metal layer 112 may include copper, and the skin layer 114 may include heterogeneous metals including copper and nickel. For example, the skin layer 114 may include Cu₁₋ₓNiₓ (x is 0.2 to 0.8). In some example embodiments, the skin layer 114 may include any one of Cu₁₋ₓNiₓ (x is 0.3 to 0.7), Cu₁₋ₓNiₓ (x is 0.35 to 0.65), Cu₁₋ₓNiₓ (x is 0.4 to 0.6), and Cu₁₋ₓNiₓ (x is 0.45 to 0.55).

In some example embodiments, the metal layer 112 may have a thickness of 100 nanometers to 20 micrometers, and the skin layer 114 may have a first thickness t11 of about 150 angstroms to about 300 angstroms.

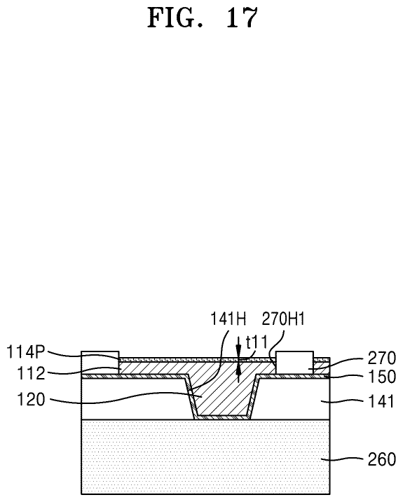

In some example embodiments, the skin layer 114 may include an alloy of copper and nickel or a compound of copper and nickel, which are formed by diffusion of copper atoms contained in the metal layer 112 into a finishing layer 114P (see FIG. 17) formed on the upper surface of the metal layer 112. In a manufacturing process, a finishing layer 114P containing nickel may be formed on the upper surface of the metal layer 112, and a first redistribution insulation layer 140 may be formed on the finishing layer 114P. Then, the first redistribution insulation layer 140 is cured at a temperature of about 200° C. to about 300° C. While curing the first redistribution insulation layer 140, copper atoms contained in the metal layer 112 are diffused into the finishing layer 114P, thereby forming a skin layer 114 including copper and nickel. As the finishing layer 114P is formed with a first thickness t11 of 150 to 300 angstroms, copper atoms may be sufficiently diffused into the finishing layer 114P during the curing process, alloying of nickel and copper may occur in the entire region of the finishing layer 114P, and thus the skin layer 114 may have a relatively homogeneous composition (e.g., content of nickel and content of copper) over the entire thickness t11.

In some other example embodiments, the metal layer 112 may include copper and/or a copper alloy including at least one metal element, and the skin layer 114 may include copper and nickel. For example, the skin layer 114 may be formed by diffusion of copper atoms included in the metal layer 112 into the finishing layer 114P during the curing process of the first redistribution insulation layer 140 performed at a temperature of about 200° C. to about 300° C.

FIG. 2 illustrates an example in which the plurality of first redistribution conductive patterns 110 include a first conductive pattern 110_1, a second conductive pattern 110_2, and a third conductive pattern 110_3, which are arranged at different vertical levels. The first conductive pattern 110_1, which is the lowermost first redistribution conductive pattern 110, is arranged on the upper surface of the first insulation layer 141, and the second insulation layer 142 is arranged to cover the first conductive pattern 110_1 and have an upper surface arranged at a higher level than the upper surface of the first conductive pattern 110_1. That is, the upper surface and the sidewall of the first conductive pattern 110_1 may be covered by the second insulation layer 142. The second conductive pattern 110_2 may be arranged on the second insulation layer 142, and the third insulation layer 143 may cover the second conductive pattern 110_2 on the second insulation layer 142.

Each of a plurality of first redistribution conductive patterns 110 may be integrally formed with or integrally connected to the first conductive via 120 arranged therebelow. As shown in FIG. 2, the second insulation layer 142 may include a via hole 140H, and the via hole 140H may be arranged to expose a part of the upper surface of the first conductive pattern 110_1. Among the plurality of first conductive vias 120, a second via 120_2 may be integrally connected to the bottom surface of the second conductive pattern 110_2 and arranged in the via hole 140H. The bottom surface of the second via 120_2 may be arranged on a portion of an upper surface of the first conductive pattern 110_1 exposed by the via hole 140H.

The plurality of first conductive vias 120 may include an upper surface arranged close to the connection structure 170 or the semiconductor chip 10, and a bottom surface arranged far from the connection structure 170 or the semiconductor chip 10, and the width of the upper surface thereof may be greater than the width of the bottom surface thereof.

The lower metal layers 150 may be arranged between the bottom surfaces of the plurality of first conductive patterns 110 and the first redistribution insulation layer 140 and between the sidewalls of the plurality of first conductive vias 120 and the first redistribution insulation layer 140. For example, the lower metal layers 150 may be positioned between the upper surface of the second insulation layer 142 and the bottom surface of the second conductive pattern 110_2, and between the sidewall of the second insulation layer 142 (e.g., the sidewall of the via hole 140H) and the sidewall of the second via 120_2 and may also extend between the bottom surface of the second via 120_2 and the upper surface of the first conductive pattern 110_1.

The lower metal layers 150 may function as a diffusion barrier for blocking or preventing metal atoms included in the plurality of first redistribution conductive patterns 110 from being diffused into the first redistribution insulation layer 140, and/or as a seed layer for forming the plurality of first redistribution conductive patterns 110 by a plating process. For example, the lower metal layers 150 may include at least one of titanium, titanium nitride, tantalum, tantalum nitride, ruthenium, and copper. In some example embodiments, as illustrated in FIGS. 4 and 5, the lower metal layer 150 may have a stacked structure of a first metal layer 152 and a second metal layer 154, the first metal layer 152 may be formed of titanium, and the second metal layer 154 may be formed of copper, but example embodiments are not limited thereto.

According to some example embodiments, the bottom surfaces of the lower metal layers 150 surrounding the bottom surfaces of the plurality of first conductive vias 120 may contact the top surface of the first redistribution conductive pattern 110 arranged under corresponding ones of the plurality of first conductive vias 120, respectively, and for example, may be in direct contact with the skin layer 114 of the first redistribution conductive pattern 110 arranged under a corresponding one of the plurality of first conductive vias 120. A part of the lower metal layer 150 surrounding the bottom surface of the second via 120_2, illustrated in FIG. 2, may be in direct contact with the skin layer 114 of the first conductive pattern 110_1.

For example, the skin layer 114 may have relatively low chemical reactivity with respect to the first redistribution insulation layer 140 including a PID material, and the interface between the first redistribution insulation layer 140 and the skin layer 114 may have good contact characteristics without the occurrence of voids or unconnected parts by unwanted reaction by-products or unwanted compound particles. For example, the first redistribution insulation layer 140 has good adhesive force and may be attached and/or bonded to the upper surface of the skin layer 114. In some example embodiments, the lower side of the sidewall 140HE of the via hole 140H of the first redistribution insulation layer 140 may not be lifted or may not have an irregular uneven shape, but the lower side of the sidewall 140HE of the via hole 140H of the first redistribution insulation layer 140 may have a smooth sidewall profile and may be arranged on the skin layer 114. The lower metal layer 150 may have a relatively uniform thickness on the bottom and sidewalls of the via hole 140H and may be conformally arranged.

In some example embodiments, as illustrated in FIG. 4, the via hole 140H of the first redistribution insulation layer 140 may have a flat and straight sidewall profile. The via hole 140H of the first redistribution insulation layer 140 may have an upper width greater than a lower width, the lower side of the sidewall 140HE of the first redistribution insulation layer 140 may be inclined at an acute angle with respect to the upper surface of the skin layer 114, and voids or unconnected portions may not be formed between the lower side of the sidewall 140HE of the via hole 140H of the first redistribution insulation layer 140 and the upper surface of the skin layer 114.

In some other example embodiments, as illustrated in FIG. 5, the via hole 140H of the first redistribution insulation layer 140 may have a sidewall profile with rounded corners. The lower side of the sidewall 140HE of the via hole 140H of the first redistribution insulation layer 140 may extend substantially perpendicular to the upper surface of the skin layer 114, and voids or unconnected portions may not be formed between the lower side of the sidewall 140HE of the via hole 140H of the first redistribution insulation layer 140 and the upper surface of the skin layer 114.

A plurality of first top pads 134 may be arranged to be surrounded by the uppermost first redistribution insulation layer 140 when viewed in a plan view, and the semiconductor chip 10 may be mounted on the plurality of first top pads 134. A connection bump 16 may be arranged between each of the plurality of first top pads 134 and the semiconductor chip 10. each pad 14 provided on the active surface (not shown) of the semiconductor chip 10 is connected to a corresponding one of the plurality of first upper pads 134 by the connection bump 16, and thus, an electrical signal and/or power may be supplied from the external connection terminal 310 to the semiconductor chip 10 through the first redistribution structure 100. For example, the connection bump 16 may include a conductive material for electrically connecting the semiconductor chip 10 with the first redistribution structure 100 that includes, for example, at least one of copper (Cu), aluminum (Al), silver (Ag), titanium (Ti), nickel (Ni), tin (Sn), and a tin alloy. The connection bump 16 may include, for example, at least one of a pillar structure, a solder bump, a solder ball, and a solder layer.

The expansion layer 160 may cover the semiconductor chip 10 on the first redistribution structure 100. The expansion layer 160 may include, for example, at least one of epoxy molding compound (EMC), resin, and silica. The expansion layer 160 may include a plurality of layers. For example, a first layer of the expansion layer 160 may directly cover the semiconductor chip 10 and the first redistribution structure 100, and one or more layers arranged on the upper surface of the first layer may serve as warpage control. In this case, a plurality of layers may be formed of the same material, but may be formed of different materials as desired.

The connection structure 170 may be arranged between the first redistribution structure 100 and the second redistribution structure 200, and may penetrate the expansion layer 160 in the vertical direction (Z direction). The connection structure 170 may include a conductive material for electrically connecting the first redistribution structure 100 with the second redistribution structure 200 that includes, for example, at least one of copper (Cu), aluminum (Al), silver (Ag), titanium (Ti), and nickel (Ni). In some example embodiments, the connection structure 170 may include copper.

The second redistribution structure 200 may include a plurality of second redistribution conductive patterns 210, a plurality of second conductive vias 220, a plurality of second top pads 230, and a plurality of second redistribution insulation layers 240. The second redistribution structure 200 may be arranged on the expansion layer 160 and the connection structure 170.

The plurality of second redistribution insulation layers 240 may include a photosensitive insulation material such as an insulation material (e.g., a photo-imageable dielectric (PID)). For example, the plurality of second redistribution insulation layers 240 may include a first insulation layer 241, a second insulation layer 242, a third insulation layer 243, and a fourth insulation layer 244, which are sequentially arranged on the expansion layer 160.

A plurality of second redistribution conductive patterns 210 may be arranged on corresponding ones of the plurality of layers constituting the plurality of second redistribution insulation layers 240, respectively, and second conductive vias 220 may be arranged to connect to one another the second redistribution conductive patterns 210 arranged at different vertical levels. The second top pad 230 may be arranged above the uppermost second redistribution conductive pattern 210.

As shown in FIG. 3, the plurality of second redistribution conductive patterns 210 may include a metal layer 212 and a skin layer 214 arranged on the upper surface of the metal layer 212. In some example embodiments, the metal layer 212 may include copper, and the skin layer 214 may include heterogeneous metals including copper and nickel. For example, the skin layer 214 may include Cu₁₋ₓNiₓ (x is 0.2 to 0.8). In some example embodiments, the skin layer 214 may have a thickness of about 150 angstroms to about 300 angstroms.

Each of the plurality of second redistribution conductive patterns 210 may be integrally formed with or integrally connected to the second conductive via 220 arranged therebelow. The plurality of second redistribution insulation layers 240 may include via holes 240H, and the plurality of second conductive vias 220 may be arranged in the via holes 240H, respectively. The lower metal layer 250 may be arranged between the bottom surface of the plurality of second redistribution conductive patterns 210 and the second redistribution insulation layer 240 and between the sidewalls of the plurality of second conductive vias 220 and the second redistribution insulation layer 240. Each of the plurality of second redistribution conductive patterns 210, the plurality of second conductive vias 220, the plurality of second top pads 230, the plurality of second redistribution insulation layers 240, and the lower metal layers 250 may have similar features as described above with respect to the plurality of first redistribution conductive patterns 110, the plurality of conductive vias 120, the plurality of first top pads 134, and the plurality of first redistribution insulation layers 140.

For example, the second conductive via 220 may include a lower surface arranged close to the connection structure 170 or the semiconductor chip 10, and an upper surface arranged far from the connection structure 170 or the semiconductor chip 10, and the width of the upper surface thereof may be greater than the width of the lower surface thereof.

The external connection terminal 310 may be arranged on the lower surface of the first redistribution structure 100. The external connection terminal 310 may electrically connect the semiconductor package 1 with an external device such as a system substrate or a main board. The external connection terminal 310 may be, for example, a solder ball, a bump, a pin, or a land. The external connection terminal 310 may include at least one of copper (Cu), aluminum (Al), silver (Ag), titanium (Ti), nickel (Ni), and tin (Sb). The external connection terminal 310 may be arranged in a fan-out structure, and the gap between the two adjacent external connection terminals 310 may be greater than the gap between the two adjacent connection bumps 16.

In some example embodiments, the semiconductor package 1 may further include a connection member 320 arranged on the second upper pad 230 of the second redistribution structure 200. The connection member 320 may connect the semiconductor package 1 to another semiconductor package. Each of the connection members 320 may be made from, for example, a solder ball. The connection member 320 may include at least one of copper (Cu), silver (Ag), gold (Au), and tin (Sn).

According to an example embodiment, in the process of forming a redistribution structure, a PID material is applied or coated on the upper surface of a redistribution conductive pattern including copper, and a redistribution insulation layer is formed by a subsequent curing process. During the curing process performed at a relatively high temperature, an undesired chemical reaction of copper and the PID material occurs on the upper surface of the redistribution conductive pattern, and the residue of the reaction by-products remains at the bottom of the via hole. When additional cleaning and etching processes are performed to remove the residue of these reaction by-products, the redistribution insulation layer may be lifted in the via hole region or have a sidewall profile with irregular uneven portions, and in this case, the interface characteristics between the redistribution conductive pattern and the redistribution insulation layer may deteriorate.

However, according to some example embodiments, a finishing layer 114F including nickel may be formed with a thickness t11 on the metal layer 112 of the first redistribution conductive pattern 110, and copper atoms in the metal layer 112 may be diffused into the finishing layer 114F during the curing process to form a skin layer 114 in which copper and nickel are uniformly alloyed on the surface of the metal layer 112. The skin layer 114 may have relatively low chemical reactivity with respect to the PID material, thereby mitigating or preventing the generation of reaction by-products, and may have excellent interfacial properties between the skin layer 114 and the first redistribution insulation layer 140. Accordingly, the reliability of the electrical connection of the semiconductor package 1 may be improved, and the manufacturing process of the semiconductor package 1 may be simplified.

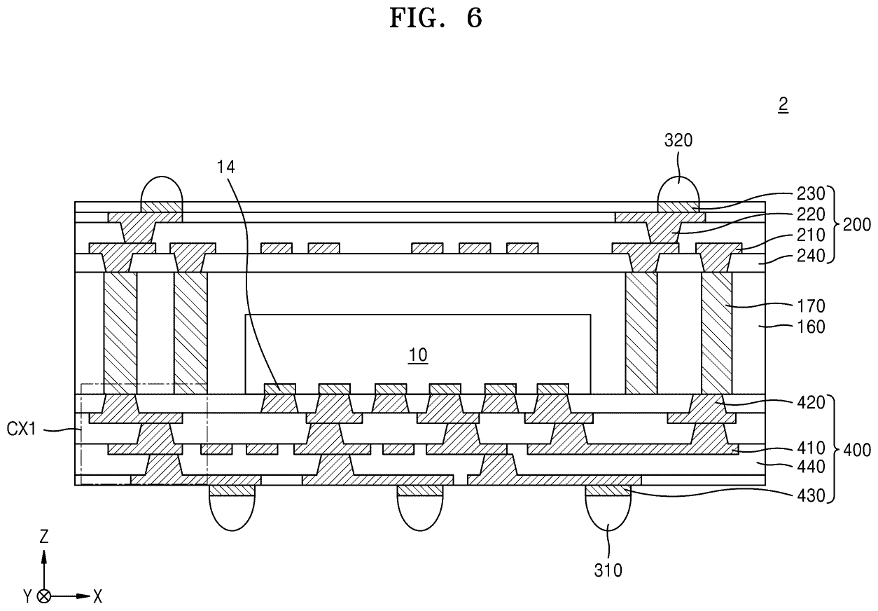

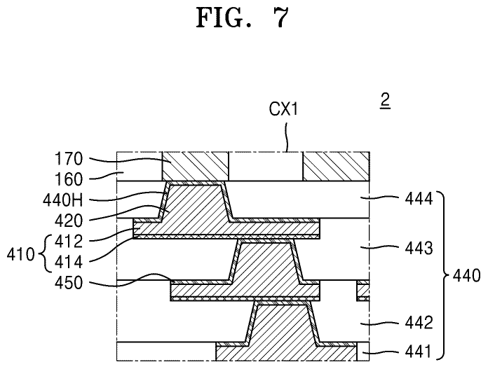

FIG. 6 is a cross-sectional view illustrating a semiconductor package 2 according to an example embodiment. FIG. 7 is an enlarged view of a portion CX1 of FIG. 6. In FIGS. 6 and 7, the same reference numerals as in FIGS. 1 to 5 refer to the same components.

Referring to FIGS. 6 and 7, the semiconductor package 2 may include a semiconductor chip 10, a first redistribution structure 400, an expansion layer 160, a connection structure 170, a second redistribution structure 200, and external connection terminals 310.

The first redistribution structure 400 may include a plurality of first redistribution conductive patterns 410, a plurality of first conductive vias 420, a plurality of bottom pads 430, and a plurality of first redistribution insulation layers 440.

Each of the plurality of first redistribution conductive patterns 410 may include a metal layer 412 and a skin layer 414 arranged on the bottom surface of the metal layer 412. Here, the bottom surface of the metal layer 412 may refer to a surface placed at a lower vertical level among two opposite surfaces of the plurality of first redistribution conductive patterns 410 that extend horizontally and face each other (e.g., a surface placed relatively further away from the semiconductor chip 10). The metal layer 412 may include copper, and the skin layer 414 may include heterogeneous metals including copper and nickel. For example, the skin layer 414 may include Cu₁₋ₓNiₓ (x is 0.2 to 0.8). In some example embodiments, the skin layer 414 may have a thickness of about 150 angstroms to about 300 angstroms.

Each of the plurality of first redistribution conductive patterns 410 may be integrally formed with or integrally connected to the first conductive via 420 arranged thereon (e.g., closer to the bottom surface of the semiconductor chip 10). The plurality of first redistribution insulation layers 440 may include via holes 440H, and the plurality of first conductive vias 420 may be arranged in the via holes 440H, respectively.

The lower metal layers 450 may be arranged between the upper surface of the plurality of first redistribution conductive patterns 410 and the first redistribution insulation layer 440 and between the sidewalls of the plurality of first conductive vias 420 and the first redistribution insulation layer 440. The first conductive vias 420 may include an upper surface arranged close to the connection structure 170 or the semiconductor chip 10, and a bottom surface arranged far from the connection structure 170 or the semiconductor chip 10, and the width of the bottom surface may be greater than the width of the upper surface.

The semiconductor chip 10 may have an active surface facing the first redistribution structure 400, and pads 14 may be provided on the active surface. The pads 14 may be arranged on the first redistribution structure 400 and may be electrically connected to the first conductive via 420 without separate connection bumps.

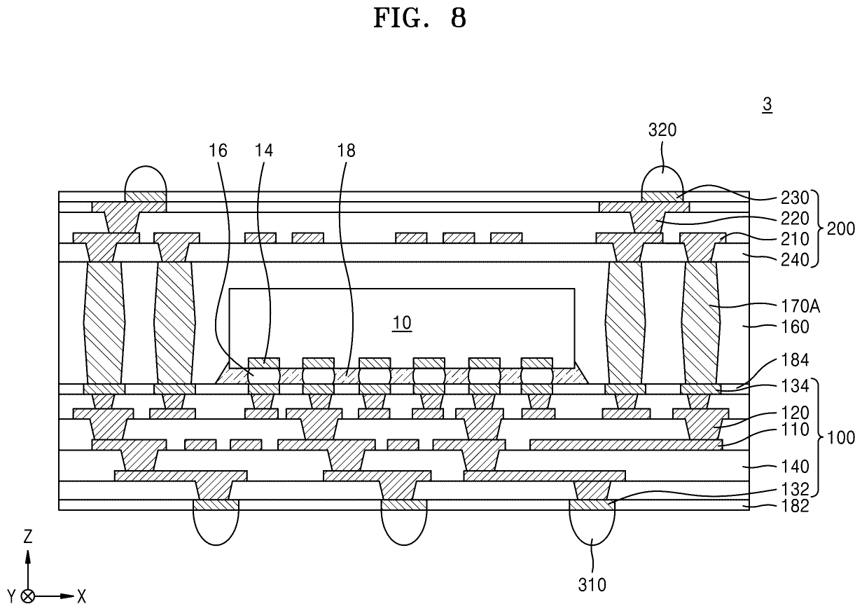

FIG. 8 is a cross-sectional view illustrating a semiconductor package 3 according to an example embodiment. In FIG. 8, the same reference numerals as in FIGS. 1 to 7 refer to the same components.

Referring to FIG. 8, the semiconductor package 3 may include a bottom solder resist layer 182 and a top solder resist layer 184 arranged on the bottom and top surfaces of the first redistribution structure 100, respectively. The bottom solder resist layer 182 may surround and protect a plurality of bottom pads 132, and the top solder resist layer 184 may surround and protect a plurality of top pads 134.

In addition, an underfill layer 18 surrounding connection bumps 16 may be placed between the semiconductor chip 10 and the first redistribution structure 100. The underfill layer 18 may be made of, for example, an epoxy resin formed by a capillary underfill method. In some example embodiments, the underfill layer 18 may cover at least a portion of the sidewall of the semiconductor chip 10.

Each of a plurality of connection structures 170A may include a conductive solder. Each of the plurality of connection structures 170A may be in direct contact with at least one of a bottom pad (not shown) of the second redistribution structure 200, a part of the lowermost second redistribution conductive pattern 210, and the lowermost second conductive via 220, and is physically and/or electrically connected thereto.

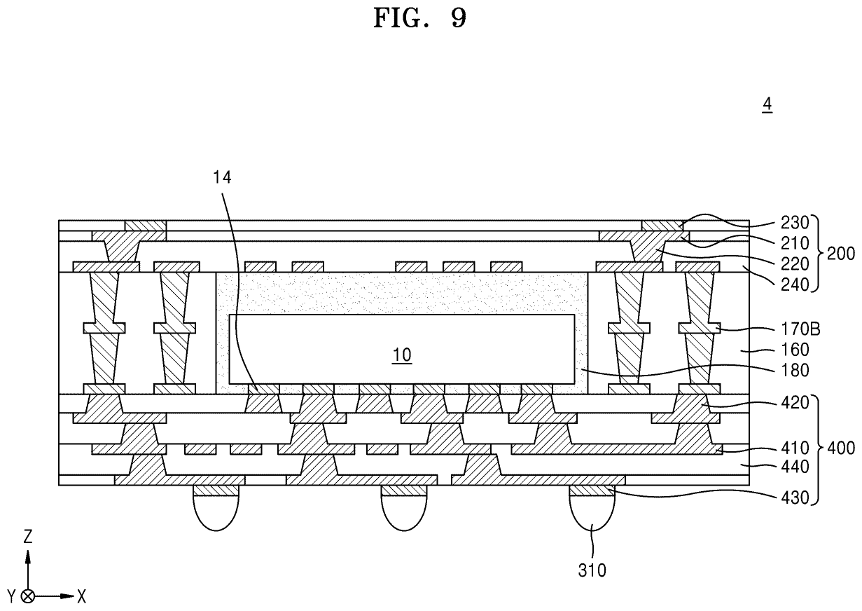

FIG. 9 is a cross-sectional view illustrating a semiconductor package 4 according to an example embodiment. In FIG. 9, the same reference numerals as in FIGS. 1 to 8 refer to the same components.

Referring to FIG. 9, the semiconductor package 4 may include a first redistribution structure 400, a connection structure 170B, and a second redistribution structure 200.

For example, each of the plurality of connection structures 170B may be a copper foil of an embedded trace substrate (ETS). Although FIG. 9 illustrates a structure in which each of the plurality of connection structures 170B has three layers, in some other example embodiments, an ETS having one to two or four or more layers may be used.

When the connection structure 170B includes a copper foil of an ETS, the semiconductor package 4 may further include a molding layer 180. The second redistribution structure 200 may be formed on an upper surface of the molding layer 180. The second redistribution structure 200 may include a multi-layered copper wire to be electrically connected to the ETS copper foil.

The pads 14 of the semiconductor chip 10 and the connection structures 170B may directly contact a part of the first redistribution structure 400. For example, the pads 14 of the semiconductor chip 10 and the connection structures 170B may directly contact a part of a plurality of first conductive vias 420.

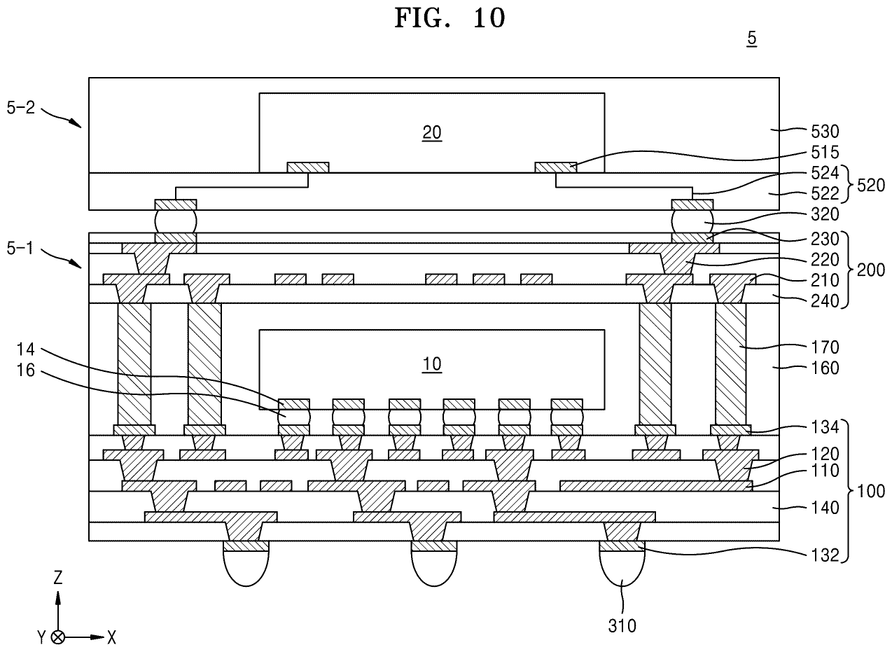

FIG. 10 is a cross-sectional view illustrating a semiconductor package 5 according to an example embodiment.

Referring to FIG. 10, the semiconductor package 5 may include a semiconductor sub-package 5-1 and a semiconductor sub-package 5-2 connected to the semiconductor sub-package 5-1 through connection members 320. For example, the semiconductor sub-packages 5-1 may include semiconductor packages 1 described with reference to FIGS. 1 to 5, but may include semiconductor packages 2, 3, and 4 described with reference to FIGS. 6 to 9.

Although the semiconductor sub-package 5-1 is shown to include one semiconductor chip 10, in some example embodiments, the semiconductor sub-package 5-1 may include two or more semiconductor chips 10 mounted on the first redistribution structure 100, and the expansion layer 160 may be arranged to cover the two or more semiconductor chips 10.

The semiconductor sub-package 5-2 may include a semiconductor chip 20, a redistribution layer 520, and a molding layer 530. The semiconductor chip 20 may be a memory chip or a logic chip. For example, the semiconductor chip 20 may be a homogeneous chip or a heterogeneous chip with the semiconductor chip 10. In some example embodiments, the semiconductor sub-package 5-2 may include a plurality of semiconductor chips 20. The redistribution layer 520 may include an insulation layer 522 and a redistribution pattern 524, and may be attached to an active surface of the semiconductor chip 20. The molding layer 530 may cover a side surface and an upper surface of the semiconductor chip 20 on the redistribution layer 520.

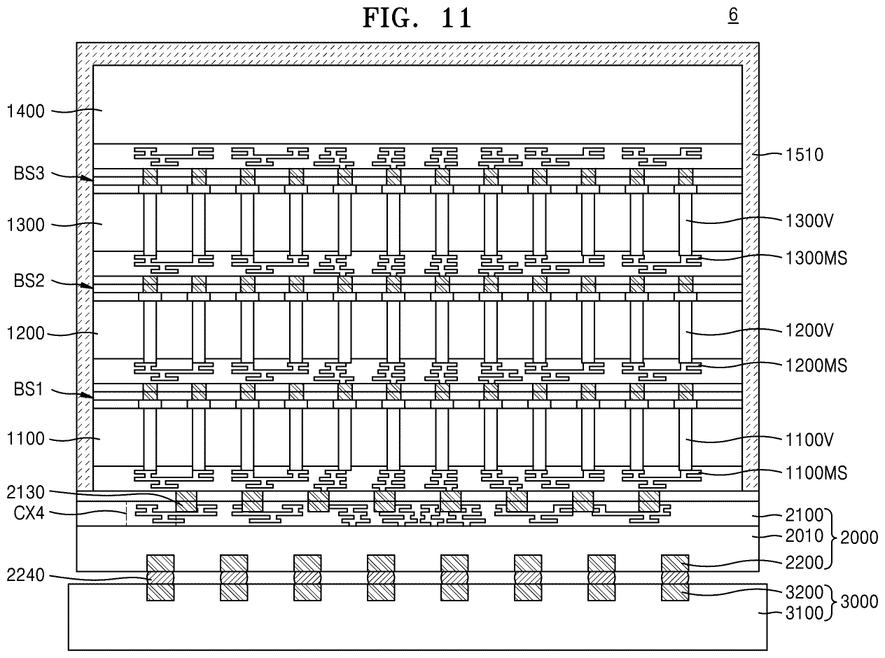

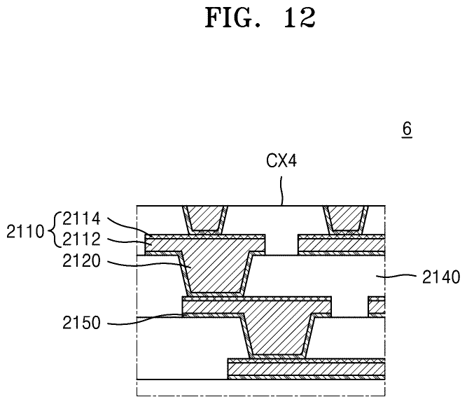

FIG. 11 is a cross-sectional view illustrating a semiconductor package 6 according to an example embodiment. FIG. 12 is an enlarged view of a portion CX4 of FIG. 11.

Referring to FIGS. 11 and 12, the semiconductor package 6 may include a first semiconductor chip 1100, a second semiconductor chip 1200, a third semiconductor chip 1300, and a fourth semiconductor chip 1400, which are stacked in a vertical direction. The first semiconductor chip 1100, the second semiconductor chip 1200, the third semiconductor chip 1300, and the fourth semiconductor chip 1400 may be vertically stacked by bonding structures BS1, BS2, and BS3 therebetween. Each of the first semiconductor chip 1100, the second semiconductor chip 1200, and the third semiconductor chip 1300 may include a first through electrode 1100V, a second through electrode 1200V, and a third through electrode 1300V, respectively. The first to third through electrodes 1100V, 1200V, and 1300V may be connected to bonding pads included in bonding structures BS1, BS2, and BS3 through wiring patterns 1100MS, 1200MS, and 1300MS, respectively.

A molding layer 1510 surrounding an upper surface and a side surface of each of the first to fourth semiconductor chips 1100, 1200, 1300, and 1400 may be further arranged.

In some example embodiments, the first to fourth semiconductor chips 1100, 1200, 1300, and 1400 may be memory chips or logic chips. For example, the first to fourth semiconductor chips 1100, 1200, 1300, and 1400 may all be the same type of memory chip, or at least one of the first to fourth semiconductor chips 1100, 1200, 1300, 1400 may be a logic chip, and the rest of the first to fourth semiconductor chips 1100, 1200, 1300, and 1400 may be memory chips.

The semiconductor package 6 may further include an interposer 2000. The interposer 2000 may include a base layer 2010, a redistribution layer 2100, and bottom pads 2200. The redistribution layer 2100 may include a redistribution conductive pattern 2110, a conductive via 2120, top pads 2130, and a redistribution insulation layer 2140.

Through vias (not shown) electrically connecting the upper pads 2130 and the lower pads 2200 may be further arranged inside the base layer 2010. The interposer 2000 and the first semiconductor chip 1100 may be attached to each other through metal-oxide hybrid bonding using the top pads 2130. In some example embodiments, the interposer 2000 and the first semiconductor chip 1100 may be connected to each other through connection bumps (not shown).

The redistribution conductive pattern 2110 may include a metal layer 2112 and a skin layer 2114, and a lower metal layer 2150 surrounding the bottom surface of the redistribution conductive pattern 2110 and the sidewall of the conductive via 2120 may be further arranged. The characteristics of the redistribution conductive pattern 2110, the conductive via 2120, and the redistribution insulation layer 2140 may be the same as or similar to those described with reference to FIGS. 1 to 5.

A main board 3000 may include a base board layer 3100 and top pads 3200, and the bottom pads 2200 of the interposer 2000 may be electrically connected to the top pads 3200 of the main board 3000 by board connection terminals 2240.

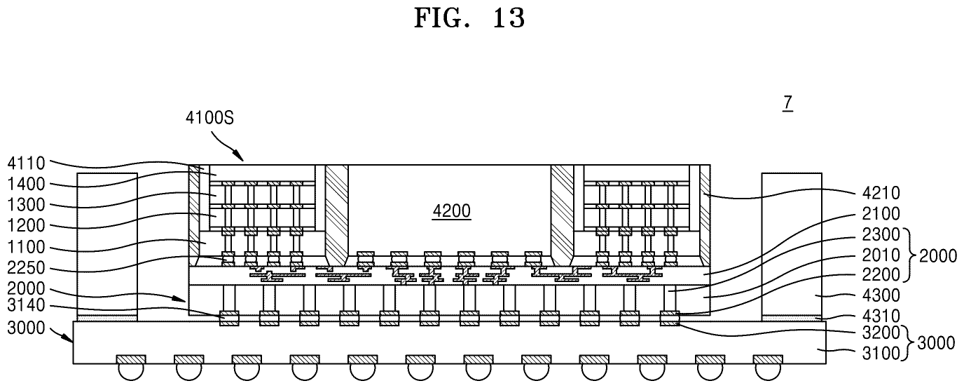

FIG. 13 is a cross-sectional view illustrating a semiconductor package 7 according to an example embodiment.

Referring to FIG. 13, the semiconductor package 7 may include a main board 3000 on which an interposer 2000 is mounted, a sub-semiconductor package 4100S including first to fourth semiconductor chips 1100, 1200, 1300, and 1400 attached to the interposer 2000, and a fifth semiconductor chip 4200. The sub-semiconductor package 4100S may correspond to the semiconductor package 6 described with reference to FIG. 12. In addition, the semiconductor package 7 may be referred to as a system.

Although FIG. 13 illustrates that the semiconductor package 7 includes two sub-semiconductor packages 4100S, the inventive concepts are not limited thereto. For example, the semiconductor package 7 may include one sub-semiconductor package 4100S or three or more sub-semiconductor packages 4100S.

The first to fourth semiconductor chips 1100, 1200, 1300, and 1400 are DRAM, SRAM, flash memory, electrically erasable and programmable read-only memory (EEPROM), PRAM, magnetic random access memory (MRAM), or RRAM. In some example embodiments, the first semiconductor chip 1100 may not include a memory cell. The first semiconductor chip 1100 may include a serial-parallel conversion circuit, a design for test (DFT), a test logic circuit such as a joint test action group (JTAG), a memory built-in self-test (MBIST), and a signal interface circuit such as a physical interface layer (PHY). The second to fourth semiconductor chips 1200, 1300, and 1400 may include memory cells. For example, the first semiconductor chip 1100 may be a buffer chip for controlling the second to fourth semiconductor chips 1200, 1300, and 1400.

In some example embodiments, the first semiconductor chip 1100 may be a buffer chip for controlling high bandwidth memory (HBM) DRAM, and the second to fourth semiconductor chips 1200, 1300, and 1400 may be memory cell chips having cells of HBM DRAM controlled by the first semiconductor chip 1100. The first semiconductor chip 1100 may be referred to as a buffer chip or a master chip, and the second to fourth semiconductor chips 1200, 1300, and 1400 may be referred to as a slave chip or a memory cell chip. The sub-semiconductor package 4100S including the first to fourth semiconductor chips 1100, 1200, 1300, and 1400 may be referred to as an HBM DRAM device.

The sub-semiconductor package 4100S may further include a chip molding layer 4110 surrounding the second to fourth semiconductor chips 1200, 1300, and 1400 on an upper surface of the first semiconductor chip 1100. The chip molding layer 4110 may be made of, for example, an EMC.

The fifth semiconductor chip 4200 may be a logic semiconductor chip. The fifth semiconductor chip 4200 may include, for example, one of a central processing unit (CPU) chip, a graphical processing unit (GPU) chip, an application processor (AP) chip, an application specific integrated circuit (ASIC), or other processing chips.

At least one sub-semiconductor package 4100S may be electrically connected onto the interposer 2000 by connection bumps 2250, and a plurality of fifth semiconductor chips 4200 may be attached onto the interposer 2000 by the connection bumps 2250 and electrically connected to the interposer 2000. In some example embodiments, at least one sub-semiconductor package 4100S and a plurality of fifth semiconductor chips 4200 may be attached and electrically connected onto the interposer 2000 by bonding pads (not shown).

The interposer 2000 may include a base layer 2010, a redistribution layer 2100, and bottom pads 2200. Through vias 2300 electrically connecting the upper pads 2130 and the lower pads 2200 may be further arranged inside the base layer 2010. As described with reference to FIGS. 11 and 12, the redistribution layer 2100 may include a redistribution conductive pattern 2110, a conductive via 2120, a top pad 2130, and a redistribution insulation layer 2140. The characteristics of the redistribution conductive pattern 2110, the conductive via 2120, and the redistribution insulation layer 2140 may be the same as or similar to those described with reference to FIGS. 1 to 5.

The semiconductor package 7 may further include, on the interposer 2000, a package molding layer 4210 surrounding at least one sub-semiconductor package 4100S and the plurality of fifth semiconductor chips 4200. The package molding layer 4210 may be made of, for example, an EMC.

The semiconductor package 7 may further include a stiffener structure 4300 attached to the main board 3000. The stiffener structure 4300 may be attached to the main board 3000 with a stiffener thermal interface material layer 4310 therebetween. The stiffener structure 4300 may be arranged to be spaced apart from at least one sub-semiconductor package 4100S and the plurality of fifth semiconductor chips 4200. The stiffener structure 4300 may extend, in a plan view (e.g., a top-view), along the edge of the main board 3000, thereby surrounding at least one sub-semiconductor package 4100S and the plurality of fifth semiconductor chips 4200.

The stiffener structure 4300 may be made of metal. For example, the stiffener structure 4300 may include at least one of copper, nickel, and stainless steel. The stiffener thermal interface material layer 4310 may be made of a material capable of maintaining electrical insulation properties by including insulation material. The stiffener thermal transfer material layer 4310 may include, for example, an epoxy resin. The stiffener thermal interface material layer 4310 may include, for example, mineral oil, grease, gap filler putty, phase change gel, phase change material pads, or powder filled epoxy. For example, the stiffener structure 4300 may have a vertical height of about 500 μm to about 800 μm.

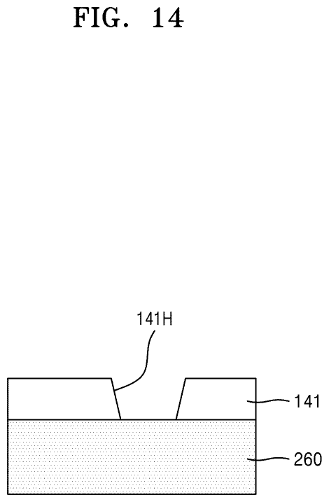

FIGS. 14 to 21 are cross-sectional views illustrating a method of manufacturing a semiconductor package, according to an example embodiment. FIGS. 14 to 21 may correspond to a method of manufacturing the semiconductor package 1 described with reference to FIGS. 1 to 5.

Referring to FIG. 14, a first insulation layer 141 having a first via hole 141H may be formed on a support carrier 260.

In some example embodiments, the first insulation layer 141 may be formed by applying or coating a photosensitive insulation material, such as a PID material, and curing the coated insulation material. For example, in order to form the first via hole 141H in the first insulation layer 141, an exposure process is performed on a part of the first insulation layer 141, the part of the first insulation layer 141 is removed by a development process, and then a curing process is performed to cure the first insulation layer 141.

In some example embodiments, the first via hole 141H may have an inclined sidewall such that the width of the upper surface thereof is greater than the width of the lower surface thereof. In some example embodiments, after the curing process, the first via hole 141H may be formed to have a rounded edge as illustrated in FIG. 5.

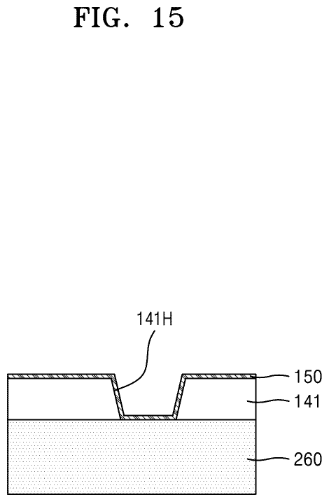

Referring to FIG. 15, a lower metal layer 150 may be formed on the first insulation layer 141 and on the inner wall of the first via hole 141H.

In some example embodiments, the lower metal layer 150 may be formed in a two-layer structure including a first metal layer 151 (see FIG. 4) and a second metal layer 152 (see FIG. 4). For example, the lower metal layer 150 may be formed by sequentially forming the first metal layer 151 and the second metal layer 152 on the first insulation layer 141 and the inner wall of the first via hole 141H. In some example embodiments, the lower metal layer 150 may be formed by sputtering, a physical vapor deposition process, electron beam evaporation, or the like.

In some example embodiments, the lower metal layers 150 may include at least one of titanium, titanium nitride, tantalum, tantalum nitride, ruthenium, and copper. In some example embodiments, the first metal layer 151 may include titanium and the second metal layer 152 may include copper, but the inventive concepts are not limited thereto.

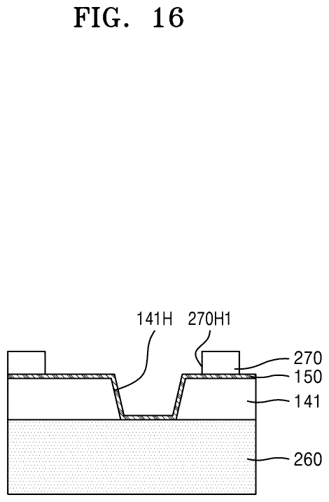

Referring to FIG. 16, a photoresist layer 270 may be formed on the lower metal layer 150. The photoresist layer 270 may include a first opening 270H1, and the first opening 270H1 may be arranged at a position vertically overlapping the first via hole 141H of the first insulation layer 141.

Referring to FIG. 17, a metal layer 112 may be formed in the first opening 270H1 of the photoresist layer 270.

In some example embodiments, the metal layer 112 may be formed using an electroplating process or an electroless plating process. In some example embodiments, the metal layer 112 may be formed using copper or copper alloy. The metal layer 112 may be formed on the lower metal layer 150 to have a thickness sufficiently large to fill the inside of the first via hole 141H of the first insulation layer 141 and the inside of the first opening 270H in the photoresist layer 270.

Here, a portion of the metal layer 112 filled in the first via hole 141H of the first insulation layer 141 may be referred to as the first conductive via 120.

Thereafter, a finishing layer 114P may be formed on the metal layer 112.

In some example embodiments, the finishing layer 114P may be formed using nickel by an electroplating process or an electroless plating process. The finishing layer 114P may be formed to have a first thickness t11 of 150 angstroms to 300 angstroms.

As illustrated in FIG. 17, the finishing layer 114P may be formed to cover the entire upper surface of the metal layer 112, and the upper surface of the metal layer 112 may not be exposed to the outside.

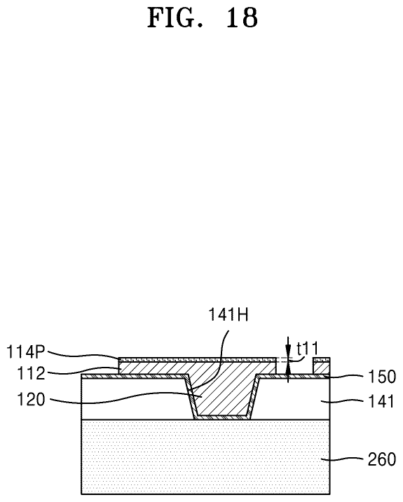

Referring to FIG. 18, the photoresist layer 270 may be removed, and the upper surface of the lower metal layer 150 arranged on the upper surface of the first insulation layer 141 may be exposed again.

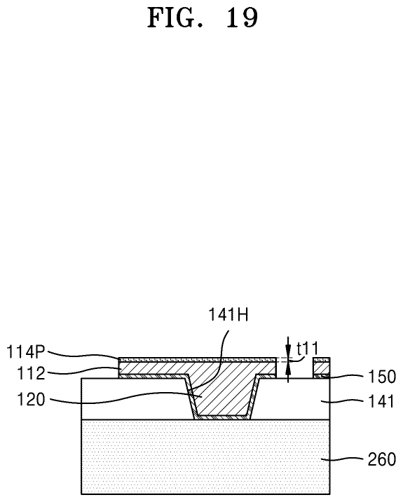

Referring to FIG. 19, a portion of the lower metal layer 150 not covered by the metal layer 112 and the finishing layer 114P may be removed.

In some example embodiments, the removal process of the lower metal layer 150 may be a wet etching process. For example, a portion of the lower metal layer 150 not covered by the metal layer 112 and the finishing layer 114P may be removed by the wet etching process, and the upper surface of the first insulation layer 141 may be exposed again.

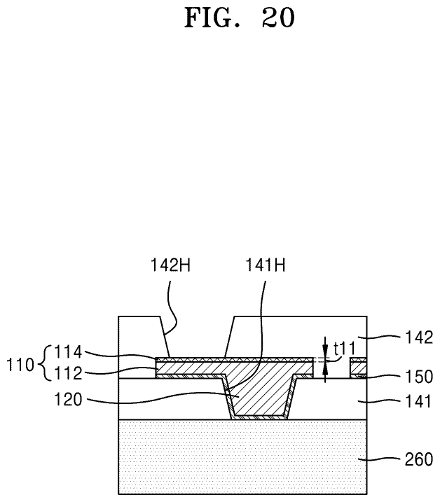

Referring to FIG. 20, a second insulation layer 142 covering the metal layer 112 and the finishing layer 114P may be formed on the first insulation layer 141. The second insulation layer 142 may be formed to have a thickness sufficiently large to completely cover the metal layer 112 and the finishing layer 114P, and the second insulation layer 142 may have an upper surface arranged at a higher vertical level than the upper surface of the finishing layer 114P.

In some example embodiments, the second insulation layer 142 may be formed by applying or coating a photosensitive insulation material, such as a PID material, and curing the coated insulation material. For example, a second via hole 142H may be formed in the second insulation layer 142 by performing an exposure process on a part of the second insulation layer 142, removing the part of the second insulation layer 142 by a development process, and then performing a curing process to thereby cure the second insulation layer 142.

In some example embodiments, the curing process of the second insulation layer 142 may be performed at a temperature of about 200° C. to about 300° C. For example, in the curing process, copper atoms included in the metal layer 112 may be diffused into the finishing layer 114P, and thus the finishing layer 114P may be converted into the skin layer 114.

In some example embodiments, the skin layer 114 may include an alloy of copper and nickel and/or a compound of copper and nickel, for example, Cu₁₋ₓNiₓ (x is 0.2 to 0.8). In some example embodiments, the skin layer 114 may include any one of Cu₁₋ₓNiₓ (x is 0.3 to 0.7), Cu₁₋ₓNiₓ (x is 0.35 to 0.65), Cu₁₋ₓNiₓ (x is 0.4 to 0.6), and Cu₁₋ₓNiₓ (x is 0.45 to 0.55).

As the finishing layer 114P is formed with a first thickness t11 of 150 to 300 angstroms, copper atoms may be sufficiently diffused into the finishing layer 114P during the curing process, alloying of nickel and copper may occur in the entire region of the finishing layer 114P, and thus the skin layer 114 may have a relatively homogeneous composition (for example, content of nickel and content of copper) entirely over the thickness t11.

The metal layer 112 and the skin layer 114 arranged on the upper surface of the metal layer 112 may be referred to as a redistribution conductive pattern 110. For example, the skin layer 114 may have a relatively low chemical reactivity to the PID material constituting the second insulation layer 142, and thus, reaction by-products or compound particles may not be generated on the upper surface of the skin layer 114 after the curing process. In addition, the skin layer 114 may have relatively excellent adhesion properties to the PID material constituting the second insulation layer 142, and accordingly, the lower side of the sidewall of the second via hole 142H of the second insulation layer 142 may not be lifted or may not have an irregular uneven shape. A lower side of the sidewall of the second via hole 142H of the second insulation layer 142 has a smooth sidewall profile and may be arranged on the skin layer 114.

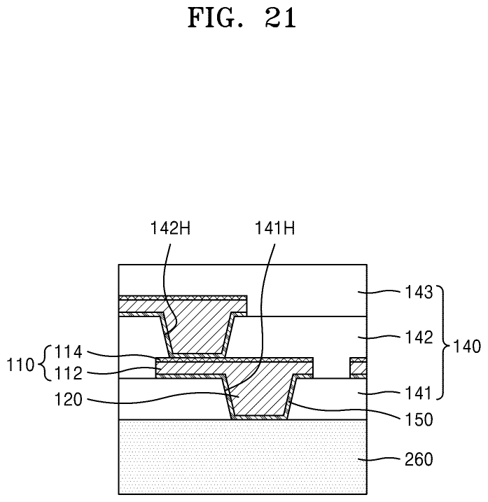

Referring to FIG. 21, a lower metal layer 150 may be formed on the second insulation layer 142 and on the inner wall of the second via hole 142H. Afterwards, the processes described with reference to FIGS. 16 to 20 may be repeatedly performed to form the first redistribution structure 100 including a plurality of first redistribution insulation layers 140, a plurality of first conductive vias 120, and a plurality of first redistribution conductive patterns 110.

Referring back to FIG. 1, a photoresist layer (not shown) having an opening (not shown) may be formed on the first redistribution structure 100, and the photoresist layer may be removed after forming a connection structure 170 in the opening.

Thereafter, a semiconductor chip 10 may be mounted on the first redistribution structure 100 using connection bumps 16, and an expansion layer 160 surrounding the semiconductor chip 10 and the connection structure 170 may be formed.

Thereafter, the second redistribution structure 200 may be formed by performing the processes described with reference to FIGS. 14 to 21.

The semiconductor package 1 may be completed by the processes described above.

In general, there is a problem that an undesired chemical reaction between copper and PID material occurs during the curing process of the PID material, and the residue of the reaction by-products remains at the bottom of the via hole. When additional cleaning and etching processes are performed to remove the residue of these reaction by-products, the redistribution insulation layer may be lifted in the via hole region or have a sidewall profile with irregular uneven portions, and in this case, the interface characteristics between the redistribution conductive pattern and the redistribution insulation layer may deteriorate.

However, according to the disclosed manufacturing method of the semiconductor package 1, copper atoms in the metal layer 112 may be diffused into the finishing layer 114P in the curing process, and thus the skin layer 114 including an alloy of copper and nickel or a compound of copper and nickel may have a uniform composition over the entire thickness thereof. Because the skin layer 114 has low chemical reactivity to the PID material, reaction by-products may not be generated during the curing process, and thus, additional cleaning and etching processes to remove the residue of the unwanted reaction by-products may be omitted, thereby simplifying the process.

While the inventive concepts have been particularly shown and described with reference to some example embodiments thereof, it will be understood that various changes in form and details may be made therein without departing from the spirit and scope of the following claims.

1. A semiconductor package comprising:
a redistribution structure including a plurality of redistribution conductive patterns, a plurality of conductive vias connected to at least one of the plurality of redistribution conductive patterns, a plurality of lower pads connected to the plurality of conductive vias, and a plurality of redistribution insulation layers and the plurality of redistribution conductive patterns alternating with each other;
a semiconductor chip on the redistribution structure; and
an external connection terminal attached to the plurality of lower pads of the redistribution structure, wherein
each of the plurality of redistribution conductive patterns comprises,
a metal layer including copper, and
a skin layer on an upper surface of the metal layer and including copper and nickel.

2. The semiconductor package of claim 1, wherein the skin layer includes Cu₁₋ₓNiₓ (x is 0.2 to 0.8).

3. The semiconductor package of claim 1, wherein
the skin layer covers an entire upper surface of the metal layer, and
the skin layer is between the upper surface of the metal layer and a corresponding one of the plurality of redistribution insulation layers.

4. The semiconductor package of claim 3, wherein
the skin layer does not cover a sidewall of the metal layer, and
the sidewall of the metal layer is surrounded by a corresponding one of the plurality of redistribution insulation layers.

5. The semiconductor package of claim 1, wherein
a first redistribution insulation layer of the plurality of redistribution insulation layers includes a first via hole,
a first conductive via of the plurality of conductive vias is in the first via hole,
the skin layer of a first redistribution conductive pattern of the plurality of redistribution conductive patterns is between a first portion of the metal layer of the first redistribution conductive pattern and the first conductive via, and
the first portion of the metal layer is below the first conductive via.

6. The semiconductor package of claim 5, wherein
the redistribution structure further comprises a lower metal layer surrounding a sidewall and a bottom surface of the first conductive via, and
a bottom surface of the lower metal layer and the skin layer of the first redistribution conductive pattern are in direct contact with each other.

7. The semiconductor package of claim 1, wherein the skin layer has a thickness of 150 angstroms to 300 angstroms.

8. The semiconductor package of claim 1, wherein the plurality of redistribution insulation layers comprise a photo-imageable dielectric (PID) material.

9. A semiconductor package comprising:
a first redistribution structure including a plurality of first redistribution conductive patterns, a plurality of first conductive vias connected to at least one of the plurality of first redistribution conductive patterns, a plurality of lower pads connected to the plurality of first conductive vias, and a plurality of first redistribution insulation layers and the plurality of first redistribution conductive patterns alternating with each other;
a semiconductor chip on the first redistribution structure;
a connection structure on the first redistribution structure and spaced apart from the semiconductor chip in a horizontal direction; and
a second redistribution structure on the connection structure and including a plurality of second redistribution conductive patterns, a plurality of second conductive vias connected to at least one of the plurality of second redistribution conductive patterns, and a plurality of second redistribution insulation layers and the plurality of second redistribution conductive patterns alternating with each other, wherein
at least one of the plurality of first redistribution conductive patterns and the plurality of second redistribution conductive patterns comprises,
a metal layer including copper, and
a skin layer on an upper surface of the metal layer and including copper and nickel.

10. The semiconductor package of claim 9, wherein
the skin layer includes Cu₁₋ₓNiₓ (x is 0.2 to 0.8), and
the skin layer has a thickness of 150 angstroms to 300 angstroms.

11. The semiconductor package of claim 9, wherein
the skin layer covers an entire upper surface of the metal layer, and
the skin layer does not cover a sidewall of the metal layer.

12. The semiconductor package of claim 11, wherein
the skin layer is between the upper surface of the metal layer and a corresponding one of the plurality of first redistribution insulation layers, and
the sidewall of the metal layer is surrounded by a corresponding one of the plurality of first redistribution insulation layers.

13. The semiconductor package of claim 9, wherein
the first redistribution structure further comprises a lower metal layer covering a sidewall and a bottom surface of a first conductive via of the plurality of first conductive vias and on a bottom surface of a first redistribution conductive pattern of the plurality of first redistribution conductive patterns,
the lower metal layer and the skin layer of the first redistribution conductive pattern are between a portion of the metal layer of the first redistribution conductive pattern and the first conductive via, and
the portion of the metal layer of the first redistribution conductive pattern is below the first conductive via.

14. The semiconductor package of claim 13, wherein the first conductive via and the first redistribution conductive pattern are portions of an integral structure, respectively.

15. A semiconductor package comprising:
a first redistribution structure;
a semiconductor chip on the first redistribution structure;
a connection structure on the first redistribution structure and spaced apart from the semiconductor chip in a horizontal direction,
a second redistribution structure on the connection structure and being at a higher vertical level than the semiconductor chip; and
an external connection terminal on a bottom surface of the first redistribution structure,
wherein the first redistribution structure comprises,
a first conductive pattern,
a first insulation layer covering the first conductive pattern and including a first via hole exposing a portion of an upper surface of the first conductive pattern,
a conductive via in the first via hole and on the portion of the upper surface of the first conductive pattern,
a second conductive pattern on the first insulation layer and integrally connected to the conductive via, and
a second insulation layer covering the second conductive pattern, and
wherein each of the first conductive pattern and the second conductive pattern comprises,
a metal layer including copper, and
a skin layer on an upper surface of the metal layer, and including Cu₁₋ₓNiₓ (x is 0.2 to 0.8).

16. The semiconductor package of claim 15, wherein the skin layer has a thickness of 150 angstroms to 300 angstroms.

17. The semiconductor package of claim 15, wherein
the skin layer of the first conductive pattern covers an entirety of the upper surface of the metal layer of the first conductive pattern, and
the skin layer of the first conductive pattern does not cover a sidewall of the metal layer of the first conductive pattern.

18. The semiconductor package of claim 17, wherein
the skin layer of the first conductive pattern is between the upper surface of the metal layer of the first conductive pattern and the first insulation layer, and
the sidewall of the metal layer of the first conductive pattern is in contact with the first insulation layer.

19. The semiconductor package of claim 18, wherein
the redistribution structure further comprises a lower metal layer surrounding a sidewall and a bottom surface of the conductive via, and
an upper surface of the skin layer of the first conductive pattern that is on a bottom of the first via hole is in contact with the lower metal layer.

20. The semiconductor package of claim 15, wherein the first insulation layer and the second insulation layer comprise a photo-imageable dielectric (PID) material.

21.-30. (canceled)
